(19) United States
(12) Patent Application Publication
(10) Pub. No.: US 2007/0078551 A1
(43) Pub. Date: Apr. 5, 2007

(54) Sound effect adjustment system and method of the same

(76) Inventors: Cheng-Shing Lai, Taipei Hsien (TW); Wan-Jun Liu, Nanking City (CN)

Correspondence Address: NORTH AMERICA INTELLECTUAL PROPERTY CORPORATION, P.O. BOX 506, MERRIFIELD, VA, 22116, US

(21) Appl. No.: 11/535,078

(22) Filed: Sep. 26, 2006

(30) Foreign Application Priority Data
Oct. 4, 2005 (TW) 094134735

(51) Int. Cl. G06F 17/00; H03G 3/00

(52) U.S. Cl. 700/94; 381/61

(57) ABSTRACT

A sound effect adjustment system includes a memory unit and an adjustment unit. The adjustment unit is able to automatically adjust the play mode of a playback apparatus based on the file type or the file location of the music file stored in the memory unit. Therefore, the user can play the music file without worrying about adjustments of intensities of different audio frequencies.

### BACKGROUND OF THE INVENTION

1. Field of the Invention

The present invention relates to a sound effect adjustment system and method, and more specifically, to a method and system which provides sound effect adjustment in a broadcast apparatus.

2. Description of the Prior Art

Along with the rapid development of electronic industry, it is not uncommon to play music with advance sound effect on playback apparatus or multimedia system. Therefore, the requirement for audio performance has become more and more stringent. Furthermore, due to the development of music compression technology, such as MP3 and MPEG Audio Layer 3, the file size of a digitized music file can be compressed to be much smaller without sacrificing high audio performance. And based on the compression technology, tremendous amount of digital music files is able to be easily stored in the storage media and can be easily distributed over the Internet. Besides, due to the consideration of portable feature, the multimedia playback with compression technology gradually becomes the most popular playback apparatus among various kinds of playback systems.

Please refer to FIG. 1, FIG. 1 shows a flow chart diagram of a sound effect adjustment process according to the prior art. In the prior art, the play mode for playing each music file must be adjusted by the user every time. The prior art sound effect adjustment process comprises the following consecutive steps:

Step 11: press a menu button to enter a main menu;

Step 12: browse the main menu and select the optional setting submenu;

Step 13: browse the optional setting submenu and select the sound effect option to list preset play modes for an equalizer; and

Step 14: browse the preset play modes, and select a desirable play mode.

The multimedia playback apparatus is not able to automatically select a play mode for a music file. Therefore, the user has to make selections for different music files. Consequently, there is a great need for providing a convenient sound effect adjustment system and method to overcome the inconvenience faced by the prior art.

### SUMMARY OF THE INVENTION

The present invention provides a sound effect adjustment system for use in a playback apparatus. The sound effect adjustment system comprises a memory unit installed in the playback apparatus for storing at least one music file which contains music data, and an adjustment unit for selecting a play mode of the playback apparatus according to the music data in the memory unit. The playback apparatus plays the music file based on the selected play mode.

The present invention further provides a method for playing a music file according to a music play mode. The method comprises installing a memory unit in a playback apparatus for storing at least one music file which contains music data, and providing an adjustment unit for adjusting a music play mode of the playback apparatus based on the music data stored in the memory unit. The playback apparatus plays the music file based on the selected music play mode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows the flow chart diagram of a sound effect adjustment process according to the prior art.

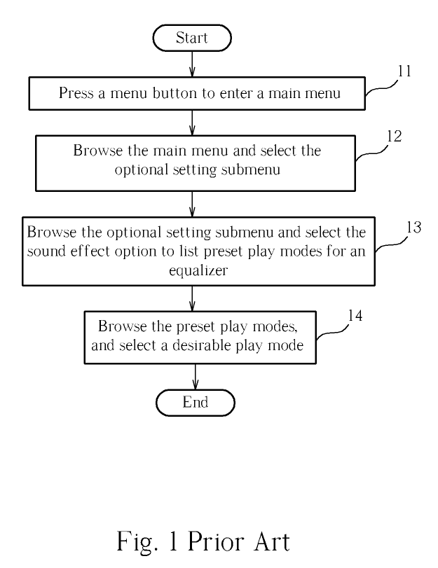

FIG. 2 shows a preferred embodiment of a schematic block diagram of the sound effect adjustment system according to the present invention.

FIG. 3 is a schematic diagram showing the operation of the adjustment unit according to the present invention.

FIG. 4 is another schematic diagram showing the operation of the adjustment unit according to the present invention.

FIG. 5 shows a flow chart diagram of a sound effect adjustment method according to the present invention.

FIG. 6 shows a flow chart diagram of a preferred embodiment of the sound effect adjustment method according to the present invention.

FIG. 7 shows a flow chart diagram of another preferred embodiment of the sound effect adjustment method according to the present invention.

### DETAILED DESCRIPTION

The foregoing aspects and many of the attendant advantages of this invention will become more readily appreciated as the same becomes better understood by reference to the following detailed description, when taken in conjunction with the accompanying drawings.

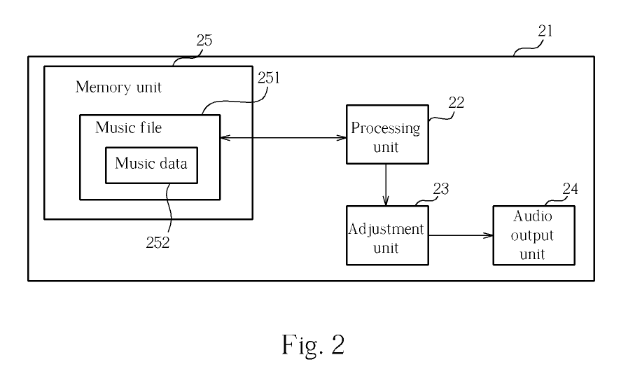

Please refer to FIG. 2. FIG. 2 shows a preferred embodiment of a schematic block diagram of a sound effect adjustment system according to the present invention, which can be applied to a multimedia playback apparatus. The sound effect adjustment system 21 in FIG. 2 comprises a processing unit 22, an adjustment unit 23 such as an equalizer, an audio output unit 24, and a memory unit 25.

The memory unit 25 comprises at least one music file 251 which contains music data 252. The music data 252 includes information to specify the file type of the music file 251 or to specify the file location of the music file 251. The processing unit 22 fetches the music file 251 and music data 252 from the memory unit 25. The adjustment unit 23 is utilized to adjust the play mode of the playback apparatus based on the music data 252. The audio output unit 24 functions to broadcast the music file 251 based on the play mode adjusted by the adjustment unit 23.

The file type of the music file 251 could be utilized to specify a certain music play mode such as a classical music mode, a rock music mode, a pop music mode, or a jazz music mode. And the file type is determined by the extension of the file name of the music file 251. The file location of the music file 251 could be represented by the current directory or the pathname of the music file 251.

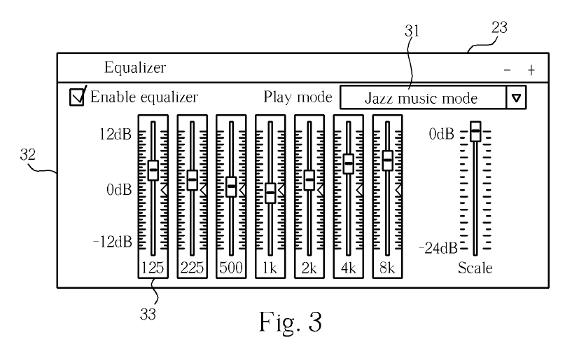

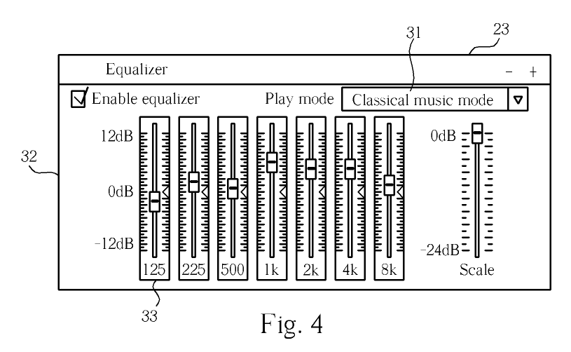

Please refer to FIGS.3 and 4. FIG.3 shows the output of the adjustment unit 23 when Jazz music mode is selected according to the present invention. FIG.4 shows the output of the adjustment unit 23 when Classical music mode is selected according to the present invention. The adjustment unit 23, which functions as an equalizer, comprises a play mode option 31 which is shown as a pull-down menu, and an adjustment interface 32 with a plurality of adjustable bars 33.

The equalizing process can be performed by adjusting the plurality of adjustable bars of the adjustment interface 32 for different audio frequency ranges. The play mode option 31 comprises a custom mode which is defined by the user, a rocky music mode, a jazz music mode, a pop music mode, and a classical music mode, etc.

Take the operation of the adjustable bar 33 for example, the adjustable bar 33 is utilized to adjust the intensity of the audio frequency of 125 Hz. The intensity of the audio frequency of 125 Hz can be amplified by pushing upward the slider of the adjustable bar 33, which results in an amplification of the low audio frequency components around 125 Hz. On the other hand, the intensity of the audio frequency of 125 Hz can be reduced by pushing downward the slider of the adjustable bar 33, which results in a reduction of the low audio frequency components around 125 Hz. The operations of the other adjustable bars can be realized in a similar manner described above and, for the sake of clarity, will not be repeated here.

Different music files generally correspond to different adjustable bar arrangements. For example, the sliders of the adjustable bars 33 in FIG.3 are disposed at different positions with sliders of the corresponding adjustable bars 33 in FIG.4 because the adjustment unit 21 in FIG.3 is in the Jazz music mode while the adjustment unit 21 in FIG.4 is in the Classical music mode. Therefore, when a music play mode is selected, the adjustment unit 23 can generate a predetermined adjustable bar arrangement for the selected music play mode. Further, the adjustment unit 23 can generate an adjustable bar arrangement according to the file location of the music file 251. Thus no more manual adjustment is required for each different music file.

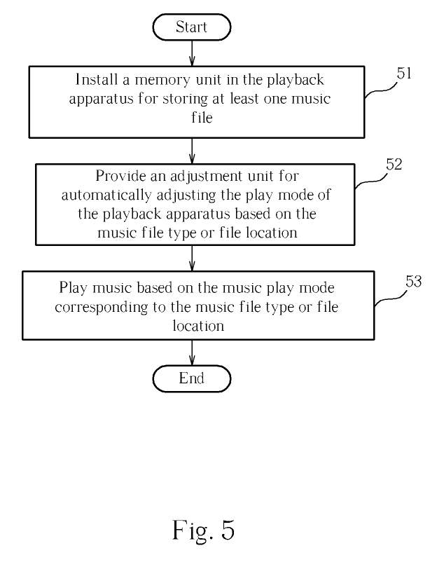

Please refer to FIG. 5, FIG. 5 shows a flow chart diagram of the sound effect adjustment method according to the present invention, which can be applied to a multimedia playback apparatus. The sound effect adjustment method comprises the following consecutive steps:

Step 51: install a memory unit in the playback apparatus for storing at least one music file which contains music data;

Step 52: provide an adjustment unit for automatically adjusting the play mode of the playback apparatus based on the music file type or file location stored in the memory unit; and

Step 53: play music based on the music play mode corresponding to the music file type or file location.

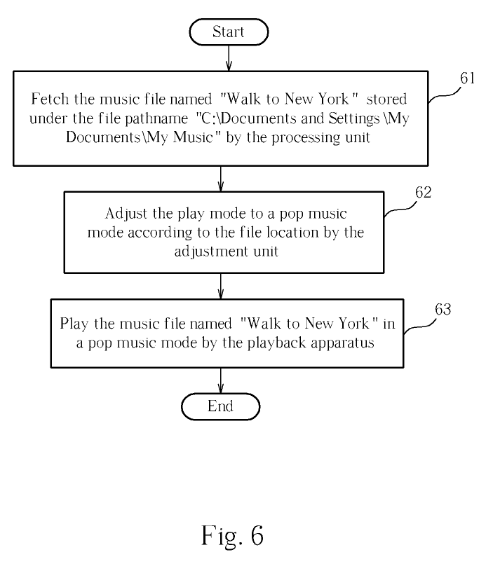

Please refer to FIG. 6, FIG. 6 shows a flow chart diagram of a preferred embodiment of the sound effect adjustment method according to the present invention. For example, if the user wants to play a music file named “Walk to New York”, the operation process comprises the following consecutive steps:

Step 61: fetch the music file named “Walk to New York”, which is stored under the file pathname “C:\ Documents and Settings\ My Documents\ My Music”, from the memory unit of the playback apparatus by the processing unit;

Step 62: adjust the play mode to a pop music mode according to the file location by the adjustment unit; and

Step 63: play the music file named “Walk to New York” in a pop music mode by the playback apparatus.

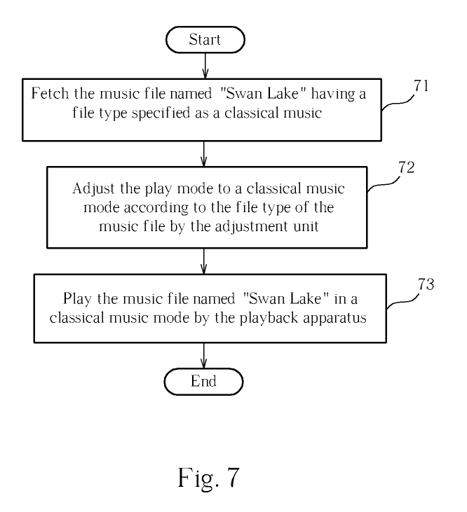

However, after playing the music file named “Walk to New York”, if the user wants to listen to classical music such as a music file named “Swan Lake” composed by Tchaihousky, the operation process is demonstrated by the flow chart diagram shown in FIG. 7. The operation process in FIG. 7 comprises the following consecutive steps:

Step 71: fetch the music file named “Swan Lake” having a file type specified as a classical music;

Step 72: adjust the play mode to a classical music mode according to the file type of the music file by the adjustment unit; and

Step 73: play the music file named “Swan Lake” in a classical music mode by the playback apparatus.

As a result, the adjustment unit is able to automatically adjust the play mode of the playback apparatus based on the file type or the file location of the music file.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A sound effect adjustment system for use in a playback apparatus, the sound effect adjustment system comprising:
a memory unit installed in the playback apparatus for storing at least one music file which contains music data; and
an adjustment unit for selecting a play mode of the playback apparatus according to the music data in the memory unit;
wherein the playback apparatus plays the music file based on the selected play mode.

2. The sound effect adjustment system of claim 1, wherein the playback apparatus is a multimedia playback system.

3. The sound effect adjustment system of claim 1, wherein the music data includes data to specify a file type of the music file.

4. The sound effect adjustment system of claim 3, wherein the file type of the music file is an extension of the filename of the music file.

5. The sound effect adjustment system of claim 1, wherein the music data includes data to specify a file location of the music file.

6. The sound effect adjustment system of claim 5, wherein the file location of the music file is represented by a pathname of the music file.

7. The sound effect adjustment system of claim 5, wherein the file location of the music file is represented by a current directory of the music file.

8. A method for playing a music file according to a music play mode comprising:
installing a memory unit in a playback apparatus for storing at least one music file which contains music data; and
providing an adjustment unit for adjusting a music play mode of the playback apparatus based on the music data stored in the memory unit;
wherein the playback apparatus plays the music file based on the selected music play mode.

9. The method of claim 8, wherein installing a memory unit in the playback apparatus is installing a memory unit in a multimedia playback apparatus.

10. The method of claim 8 further comprising:
providing a file type of the music file to represent the music data.

11. The method of claim 10, wherein the file type of the music file is an extension of the filename of the music file.

12. The method of claim 8 further comprising:
providing a file location of the music file to represent the music data.

13. The method of claim 12 further comprising: providing a current directory of the music file to represent the file location of the music file.

14. The method of claim 12 further comprising:
providing the pathname of the music file to represent the file location of the music file.
